(19) United States
(12) Patent Application Publication
(10) Pub. No.: US 2007/0102795 A1
(43) Pub. Date: May 10, 2007

(54) RADIATOR PLATE AND SEMICONDUCTOR DEVICE

(75) Inventors: Shuzo Aoki, Nagano-shi, Nagano (JP); Sumio Uehara, Nagano-shi, Nagano (JP); Meisou Chin, Nagano-shi, Nagano (JP)

Correspondence Address: RANKIN, HILL, PORTER & CLARK LLP, 4080 ERIE STREET, WILLOUGHBY, OH, 44094-7836, US

(73) Assignee: SHINKO ELECTRIC INDUSTRIES CO., LTD., Nagano-shi (JP)

(21) Appl. No.: 11/558,228

(22) Filed: Nov. 9, 2006

(30) Foreign Application Priority Data
Nov. 10, 2005 (JP) 2005-325655

(51) Int. Cl. H01L 23/495

(52) U.S. Cl. 257/675

(57) ABSTRACT

A radiator plate 20 is mounted on a back surface of a semiconductor element 11 on a substrate 10 so that heat is radiated from the semiconductor element 11. The radiator plate 20 includes first radiating fins 20b formed on the one side which is opposite to the surface facing the substrate 10 and second radiating fins 20c formed on the other side which faces the substrate 10. The second radiating fins 20c are arranged in the same direction as the first radiating fins 20b and at positions not interfering the semiconductor element 11.

### BACKGROUND OF THE INVENTION

1. Field of the Invention

This invention relates to a radiator plate for effectively radiating heat generated in a semiconductor element on a semiconductor device and the semiconductor device using the same.

2. Description of Related Art

In recent years, with advancement of high speed of a semiconductor element loaded on a semiconductor device, the heat value generated in the semiconductor element has increased. When temperature of the semiconductor element increases to a certain temperature or more, its required operation characteristic cannot be obtained. So in the semiconductor device with the semiconductor element having large quantity of generated heat, a radiator plate, radiating fin or draft fan for externally dissipating the heat generated in the semiconductor element is used to prevent the semiconductor element from being excessively heated.

FIG. 7 shows examples in which a radiator plate is attached to a semiconductor device for a memory buffer used in a memory module. In an example shown in FIG. 7A, a metallic cap 12 is attached to a substrate 10 on which a semiconductor element is loaded. In an example shown in FIG. 7B, a radiator plate 14 formed of a thick plate is attached to the substrate 10. In an example shown in FIG. 7C, a radiator plate 16 equipped with radiating fins 16a is attached to the substrate 10. In all these examples, the radiating plate is attached to a side of the substrate 10 on which the semiconductor element is mounted so that an inner surface of the cap 12 or a lower surface of the radiator plate 14, 16 abuts on a back surface of the semiconductor element.

When the heat value in the semiconductor element increases, in the technique for attaching the metallic cap or the radiator plate to the semiconductor device to thereby radiate from the semiconductor element, there is a fear that its temperature cannot be kept at a temperature capable of assuring the operating characteristic of the semiconductor element.

For example, also in the above semiconductor device for the memory buffer, when the heat value generated in the semiconductor element increases, heat is accumulated internally in the case where the metallic cap 12 is employed. Thus, sufficient radiating effect cannot be obtained. Further, in the case where the radiator plate 14, 16 is employed, when the heat value generated in the semiconductor element increases, the temperature of the semiconductor element cannot be reduced to a predetermined operating temperature or lower.

The heat radiating characteristic of the semiconductor element can be also improved by increasing a surface area of the radiator plate in such a manner that size of the radiator plate attached to the substrate or the radiating fins is increased. However, where the large radiator plate is employed, downsizing of the product is hindered. When the product where a plurality of modules are arranged in a small space as in the memory module, increasing the size of the radiating fins is restricted. In view of these facts, a radiating plate which is small in size and can give an excellent heat dissipating effect has been demanded.

### SUMMARY OF THE INVENTION

In order to solve the above problem, this invention has been accomplished. An object of this invention is to provide a radiator plate capable of effectively radiating heat generated in a semiconductor element and not impairing the operating characteristic of the semiconductor element, and a semiconductor device using this radiator plate.

In order to attain the above object, this invention provides the following configurations.

According to a first aspect of the invention, there is provided a radiator plate mounted on a substrate so as to radiate heat generated in a semiconductor element on the substrate, the radiator plate comprising:

first radiating fins provided a first surface of the radiator plate which is an opposite surface of a second surface of the radiator plate which faces the substrate; and

second radiating fins on the second surface,

wherein a longitudinal direction of the second radiating fin is the same as a longitudinal direction of the first radiating fin, and

the second radiating fin is formed at a position which does not interfering with the semiconductor element.

According to a second aspect of the invention, as set forth in the first aspect of the invention, it is preferable that the radiator plate is formed in the same square planar shape as that of the substrate; and

the second radiating fins are provided at both side edges so as to assure a space for accommodating the semiconductor element therein.

According to a third aspect of the invention, as set forth in the first aspect of the invention, it is preferable that the first radiating fin and the second radiating fin are alternately arranged on both sides of the radiator plate.

The arrangement of “alternately” means that according to the position of a recess formed between the adjacent radiating fins on the one side and the other side of the radiator plate, the radiating fin is formed on the other side and one side of the radiator plate.

According to a fourth aspect of the invention, as set forth in the first aspect of the invention, it is preferable that the radiator plate is made of aluminum subjected to anodizing processing.

This permits heat to be effectively dissipated from the radiator plate.

According to a fifth aspect of the invention, there is provided a semiconductor device comprising:

a substrate;

a semiconductor element on the substrate;

the radiator plate as set forth in the first aspect of the invention

This semiconductor device gives excellent heat dissipation from the semiconductor element and high reliability.

According to a sixth aspect of the invention, as set forth in the fifth aspect of the invention, it is preferable that the semiconductor device further comprising:

an attachment spring that attaches the radiator plate to the substrate and comprises a depressing portion for depressing the first surface,

wherein the attachment spring is made of a wire body bent so as to be U-shape in side shape viewed from a longitudinal direction of the substrate and is provided with hook portions at both ends thereof,

at least one communicating space is formed on the first surface so as to extend in a direction perpendicular to the longitudinal direction of the first radiating fin and have a width equal to or larger than that of a slit space formed between the first radiating fins adjacent to each other, and

the attachment spring is attached to the radiator plate so that the depressing portion is fit in the communicating space.

By using the attachment spring formed by bending the wire body, the radiator plate can be very easily attached to the semiconductor device.

According to a seventh aspect of the invention, as set forth in the sixth aspect of the invention, it is preferable that at least one communicating space is formed at a symmetrical center line and on both sides relative to the symmetrical center line, respectively and

the attachment spring comprising a U-shape bending portion which extend in the both sides relative to the symmetrical center line, and

the attachment spring is attached to the radiator plate so that the depressing portion is fit in the communicating space and the slit space.

In this configuration, the radiator plate surely supported by the attachment spring can be attached to the semiconductor device.

According to an eighth aspect of the invention, as set forth in the eighth aspect of the invention, it is preferable that the radiator plate is mounted in the substrate so that the hook portions of the attachment spring are fixed in fixing holes in the substrate.

In this configuration, the radiator plate can be easily attached to the semiconductor device.

According to a ninth aspect of the invention, as set forth in the sixth aspect of the invention, it is preferable that the semiconductor device further comprises a heat transfer material disposed between the substrate and the radiator plate.

The fins may be formed such that corrugated portions extend in a longitudinal direction with constant intervals each other.

Since the radiator plate according to this invention is small in size and excellent in the radiating characteristic, the radiator plate of the invention can be effectively employed as a radiator plate for the semiconductor element having a large quantity of generated heat. Further, in a semiconductor device with this radiator plate, heat can be effectively radiated from the semiconductor element so that there is provided the semiconductor device in which the operating characteristic of the semiconductor element is not impaired and high reliability is given.

### BRIEF DESCRIPTION OF THE DRAWINGS

FIG. 1 is a perspective view of the configuration of an embodiment of a radiator plate and a semiconductor device according to this invention;

FIG. 2 is a front view showing a status where a radiator plate is attached to a semiconductor device;

FIG. 3 is a plan view showing a memory module in which a radiator plate is attached to a semiconductor device;

FIG. 4 is a plan view showing a status where an attachment spring is attached to a semiconductor device;

FIG. 5 is a plan view showing a configuration of a radiator plate employed in a memory module;

FIGS. 6A and 6B are a plan view and a side view of an attachment spring; and

FIGS. 7A, 7B and 7C are a perspective view of the semiconductor device provided with a radiator plate according to the related art.

### DETAILED DESCRIPTION OF EXEMPLARY EMBODIMENTS OF THE INVENTION EMBODIMENTS

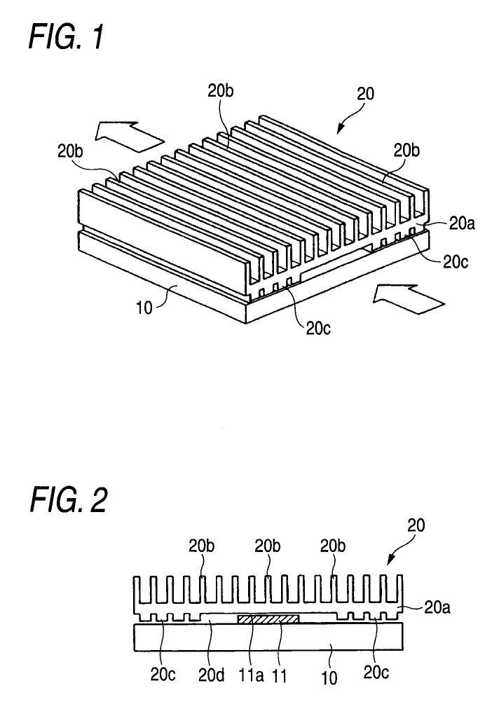

FIG. 1 is a perspective view of an exemplary configuration of the semiconductor device in which a radiator plate 20 according to this invention is attached to a substrate 10 on which a semiconductor element is loaded.

The radiator plate 20 according to this embodiment has a body 20a, first radiating fins 20b formed on the one side of the body 20a (first surface) which is opposite to the surface facing the substrate 10 and second radiating fins 20c formed on the other side of the body 20a (second surface) which faces the substrate 10. FIG. 1 shows the status where the radiator plate 20 is attached to the substrate 10 on which the semiconductor element is mounted. The radiator plate 20 is formed in the same square planar shape as that of the substrate 10, and is attached to the substrate 10 so that the second radiating fins 20c face the side of the substrate 10 on which the semiconductor element is loaded.

Pluralities of the first radiating fins 20b are arranged in parallel with constant intervals over an entire area of a planar region of the body 20a.

On the other hand, the second radiating fins 20c are arranged at positions which does not interfere with the semiconductor element loaded in the substrate 10, and the second radiating fins are also arranged so that their longitudinal direction agree with that of the first radiating fins 20b. In this embodiment, along both side edges of the body 20a, four second radiating fins 20c are formed, respectively. The region sandwiched by the second fins 20c formed on both side edges of the body 20a constitutes a region where the semiconductor element loaded on the substrate 10 is accommodated.

FIG. 2 shows the status when the semiconductor device with the radiator plate 20 attached to the substrate is seen from its front direction. A semiconductor element 11 is mounted on an element mounting face of the substrate 10 by flip-chip connection. The radiator plate 20 is attached to the substrate 10 so that the back surface of the semiconductor element 11 abuts on a lower surface of the body 20a. In order that the lower surface of the radiating plate 20 abuts on the back surface of the semiconductor element 11 when the radiator plate 20 is attached to the substrate 10, actually, the quantity of projection (projection height) of the second radiating fins 20c from the body 20a is made slightly lower than the projection height of the semiconductor element 11 from the element mounting surface of the substrate 10. Between the back surface of the semiconductor element 11 and the radiator plate 20, a heat conducting material 11a having excellent thermal conductivity is disposed so that heat is effectively conducted from the semiconductor element 11 to the radiator plate 20.

As described above, the first radiating fins 20b and second radiating fins 20c are formed in the radiator plate 20 so that their longitudinal directions are in parallel to each other. When seeing the radiator plate 20 attached to the substrate 10 from the front direction, the first radiating fins 20b and the second radiating fins 20c provide communicating spaces in a direction crossing the radiating plate in its front/rear direction. Further, since the semiconductor element 11 is located at an intermediate position between the second radiating fins 20c formed on both side edges of the radiator plate 20 so as to be apart by a predetermined distance from the second radiating fins 20c, communication spaces are formed between the semiconductor element 11 and second radiating fins 20c in the front/rear direction of the radiator plate 20.

Thus, in the semiconductor device provided with the radiator plate 20 according to this embodiment, by supplying air from a blower fan in a direction indicated by an arrow in FIG. 1, air supply is not hindered by the first radiating fins 20b and the second radiating fins 20c. Thus, by ventilating the communication spaces for the radiating fins 20b, 20c, the radiating fins 20b, 20c can be effectively cooled so that the radiating characteristic from the semiconductor element 11 can be improved.

Further, in the radiator plate 20 according to this embodiment, in the face (lower side) of the body 20a facing the substrate 10, the second radiating fins 20c are formed. Owing to this, the surface area of the entire radiator plate 20 can be made larger than a case where the radiating fins are formed only on the one side of the radiator plate. This also permits the radiating characteristic to be improved.

In this embodiment, the radiator plate 20 is made of a material of aluminum. The aluminum plate is processed to form the first radiating fins 20b and second radiating fins 20c. Thereafter, the material is subjected to anodizing processing so that the entire outer surface of the radiator plate 20 is colored in black. In this way, by using aluminum as the material of the radiator plate 20 and subjecting the surface of the material to the anodizing processing, the radiating characteristic of the radiator plate 20 can be improved as compared with the radiator plate not subjected to the anodizing processing.

Incidentally, the radiator plate may be made of a metallic material other than aluminum, e.g. copper, iron or the metallic material plated with nickel. However, if using the radiator plate with its surface being metallic glossy, this gives rise to filling of internal heat and so is not effective in order to acquire the effective radiating characteristic. Thus, when the metallic material other than aluminum is employed, by anodizing the surface of the radiator plate through oxidation processing, etc., the radiating characteristic of the radiator plate can be improved.

In the radiator plate 20 employed in this embodiment, as seen from FIG. 2, the first radiating fins 20b and the second radiating fins 20c are alternately arranged on both sides of the body 20a. Specifically, the second radiating fin 20c is formed according to a recess formed between the first radiating fins 20b adjacent to each other. On the other hand, the first radiating fin 20b is formed according to a recess formed between the second radiating fins 20c adjacent to each other. As described above, when the first radiating fins 20b and the second radiating fins 20c are alternately arranged on both sides of the body 20a, for example, the second radiating fins 20c can be formed by like half-cutting a metallic plate. Thus, the first radiating fins 20b and the second radiating fins 20c can be easily integrally formed as projections on both sides of the radiator plate 20.

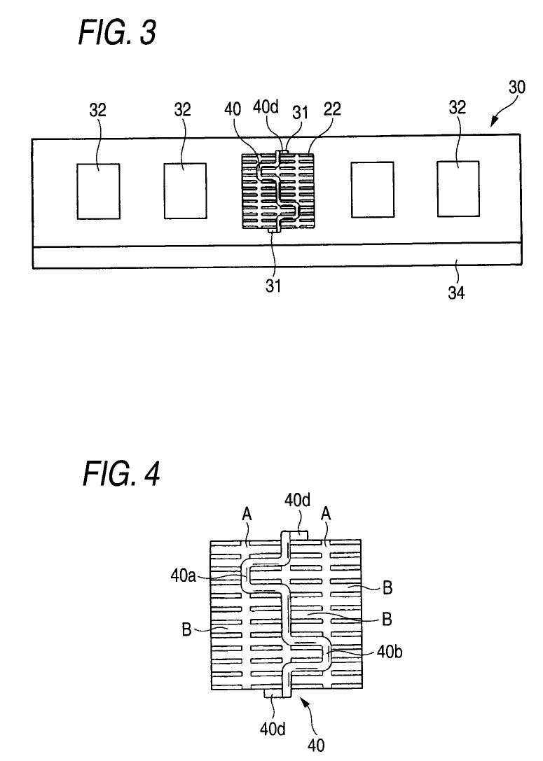

FIG. 3 shows a memory module with a semiconductor device for a memory buffer in which a radiator plate 22 is attached to the semiconductor device. On both sides of a mounting board (substrate) 30 of this memory module, mounted are a semiconductor device for a memory buffer and semiconductor memories 32. At the one side edge of the mounting board 30, a connecting terminal 34 is formed.

On the outer surface of the semiconductor device mounted on the mounting board 30, a radiator plate 22 is attached via an attachment spring 40. The attachment spring 40 serves to attach the radiator plate 22 so that it is forcibly brought into contact with the back surface of the semiconductor element loaded on the semiconductor device.

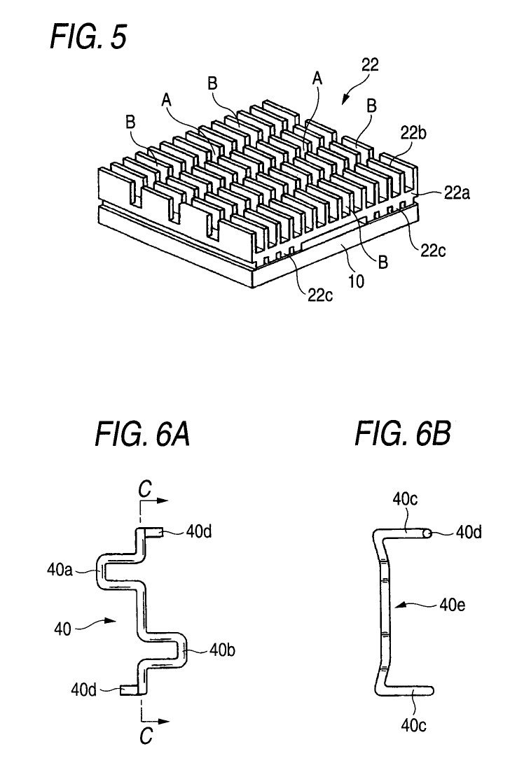

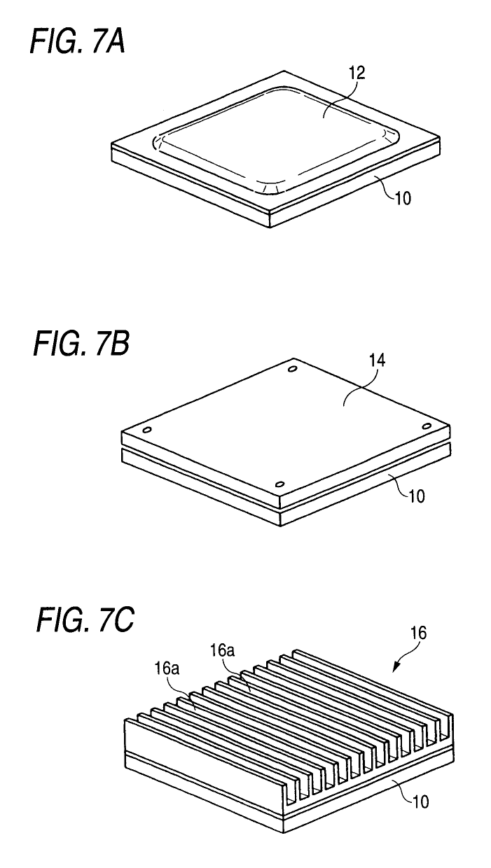

FIG. 5 is a perspective view of a radiator plate 22 which is attached to a semiconductor device using an attachment spring 40. This radiator plate 22, like the radiator plate 20 shown in FIG. 1, includes first radiating fins 22b and second radiating fins 22c formed on the one side and other side of a body 22a, respectively. In the radiator plate 22 according to this embodiment, the first radiating fins 22b are divided into four parts in the longitudinal direction so that communicating spaces A which are linearly continued in a direction perpendicular to the longitudinal direction of the radiator plate 22b. The first radiating fins 22b are divided into four parts so that three communicating spaces A are provided in an arrangement continuing in the width direction of the radiator plate 22. The communicating spaces Aare formed to have a width nearly equal to that of slit spaces B formed between the radiating fins 22b adjacent to each other in the width direction. Since the communicating spaces A are provided, when the radiator plate 22 is seen from top (in a plane direction), the end faces of rectangles of the first radiating fins 22b are aligned to provide the communicating spaces A and slit spaces B in rows and columns.

FIG. 4 is an enlarged view of the status where the attachment spring 40 is attached to the radiator plate 22. FIG. 6A is a plan view of the attachment spring 40. FIG. 6B is a side view thereof.

The attachment spring 40 is made of a wire body having elasticity. In the plane direction, as seen from FIG. 6A, the attachment spring 40 is configured so that bending portions 40a, 40b hang over rightward and leftward with respect to a symmetrical center line (C-C line) so as to form square frames (U-shapes). In the side direction, as seen from FIG. 6B, seen from a longitudinal direction of the substrate (transversal direction in FIG. 3), the attachment spring 40 is configured to provide a gate shape in which upright segments 40c, 40c are bent in an U-shape. The upright segments 40c, 40c are provided with hook portions 40d at their tips, respectively. The hook portions 40d are bent in reverse directions at the one end and the other end of the attachment spring 40.

The area formed by bending and bridging the wire body between the upright segments 40c, 40c serves as a depressing portion 40e for elastically depressing the radiator plate 22 when the radiator plate 22 is attached to the semiconductor device. As seen from FIG. 6B, in the attachment spring 40 according to this embodiment, the coupling portions between the upright segments 40c and the depressing portion 40e are bent at an acute angle so that the function of the depressing portion 40e of elastically depressing the radiator plate 22 is kept.

As seen from FIG. 4, the attachment spring 40 is attached to the radiator plate 22 by inserting the wire body of the attachment spring 40 into the communicating spaces A and slit spaces B on the side of the radiator plate 22 where the first radiating fins 22b are formed. The wire body constituting the attachment spring 40 has an outer diameter precisely fit in the communicating spaces A and slit spaces B. Thus, by inserting the wire body into the communicating spaces A and the slit spaces B, the attachment spring 40 is attached to the radiator plate 22.

The bending shape of the bending portion 40a, 40b formed in the depressing portion 40e of the attachment spring 40 is preliminary designed so as to be inserted in the communicating spaces A and the slit spaces B according to the arrangement of the radiating fins of the radiator plate 22 and the arrangement of the communicating spaces A and the slit spaces B.

The attachment spring 40 is attached to the radiator plate 22 so that the position of the upright segments 40c, 40c agrees to the position of the communicating space A passing the symmetrical center line position of the radiator plate 22. When attaching the attachment spring 40 to the radiator plate 22, the radiating fins 22b serve as guides for inserting the wire body of the attachment spring 40 into the communicating spaces A and the slit spaces B so that the attachment spring 40 can be easily positioned on the radiator plate 22. In the status where the attachment spring 40 has been mounted in the radiator plate 22, the attachment spring 40 is sandwiched by the radiating fins 22b and so preliminary fixed. Thus, with the attachment spring 40 being attached to the radiator plate 22, the radiator plate 22 can be easily attached to the semiconductor device.

The radiator plate 22 can be mounted in the mounting board 30 by attaching the attachment spring 40 to the radiator plate 22 and fixedly inserting the hook portions 40d in fixing holes 31 formed in the mounting board 30. By fixing the hook portions 40d in the fixing holes 31, the radiator plate 22 is mounted in the mounding board 30 in a state positioned relative to the semiconductor device with the internal face of the radiator plate 22 being depressed on the semiconductor element loaded on the semiconductor device.

The height of the upright segments 40c, 40c of the attachment spring 40 is set so that the radiator plate 22 elastically abuts on the back surface of the semiconductor device loaded on the semiconductor device when the hook portions 40d are fixed in the fixing holes 31 of the mounting board 30. Further, since the attachment spring 40 is provided with the bending portion 40a, 40b hanging over leftward and rightward, it serves to press the radiator plate 22 with a face contact state. Thus, the radiator plate 22 can be surely supported in a state forcibly kept in contact with the semiconductor element.

In the memory module in which the semiconductor device provided with the radiator plate 22 according to this embodiment, the radiating function of the radiator plate 22 effectively acts. So, by supplying air to the memory module from the blower fan, the operating temperature of the semiconductor element in an operating state of the semiconductor device can be lowered to a required temperature or lower.

Further, in this embodiment, the radiator plate 22 is downsized by forming its outer shape in the same shape as the planar shape of the semiconductor device. This preferably contributes to space saving. Further, since the attachment spring 40 is attached to the radiator plate in such a manner that its depressing portion 40e is fit in the communicating spaces A and slit spaces B, the depressing portion 40e of the attachment spring 40 enters internally from the end face of each the radiating fins 22b. Thus, the attachment spring 40 attached to the radiator plate is not obstructive in mounting the semiconductor device.

Further, since the radiator plate 22 is attached to the mounting board 30 using the attachment spring 40, its attaching operation can be easily executed. Furthermore, since the attachment spring 40 is formed by bending the wire body, it can be manufactured at low cost.

The attachment spring 40 employed in the above embodiment is formed to have the depressing portion 40e with the bending portion 40a, 40b having a U-shape hanging over leftward and rightward, and its wire body is fit in the adjacent spaces of the radiating fins 22b arranged in an aligned manner. The depressing portion 40e of the attachment spring 40 is not limited to such a configuration, but may be appropriately designed to be fit between the adjacent radiating fins 22b.

While the invention has been described in connection with the exemplary embodiments, it will be obvious to those skilled in the art that various changes and modification may be made therein without departing from the present invention, and it is aimed, therefore, to cover in the appended claim all such changes and modifications as fall within the true spirit and scope of the present invention.

What is claimed is:

1. A radiator plate mounted on a substrate so as to radiate heat generated in a semiconductor element on the substrate, the radiator plate comprising:
first radiating fins provided a first surface of the radiator plate which is an opposite surface of a second surface of the radiator plate which faces the substrate; and
second radiating fins on the second surface,
wherein a longitudinal direction of the second radiating fin is the same as a longitudinal direction of the first radiating fin, and
the second radiating fin is formed at a position which does not interfering with the semiconductor element.

2. The radiator plate according to claim 1,
wherein the radiator plate is formed in the same square planar shape as that of the substrate; and
the second radiating fins are provided at both side edges so as to assure a space for accommodating the semiconductor element therein.

3. The radiator plate according to claim 1,
wherein the first radiating fin and the second radiating fin are alternately arranged on both sides of the radiator plate.

4. The radiator plate according to claim 1, wherein the radiator plate is made of aluminum subjected to anodizing processing.

5. A semiconductor device comprising:
a substrate;
a semiconductor element on the substrate;
the radiator plate as set forth in claim 1.

6. The semiconductor device as set forth in claim 5, further comprising:
an attachment spring that attaches the radiator plate to the substrate and comprises a depressing portion for depressing the first surface,
wherein the attachment spring is made of a wire body bent so as to be U-shape in side shape viewed from a longitudinal direction of the substrate and is provided with hook portions at both ends thereof,
at least one communicating space is formed on the first surface so as to extend in a direction perpendicular to the longitudinal direction of the first radiating fin and have a width equal to or larger than that of a slit space formed between the first radiating fins adjacent to each other, and
the attachment spring is attached to the radiator plate so that the depressing portion is fit in the communicating space.

7. The semiconductor device according to claim 6, wherein
at least one communicating space is formed at a symmetrical center line and on both sides relative to the symmetrical center line, respectively and
the attachment spring comprising a U-shape bending portion which extend in the both sides relative to the symmetrical center line, and
the attachment spring is attached to the radiator plate so that the depressing portion is fit in the communicating space and the slit space.

8. The semiconductor device according to claim 6, wherein the radiator plate is mounted in the substrate so that the hook portions of the attachment spring are fixed in fixing holes in the substrate.

9. The semiconductor device according to claim 6, further comprising a heat transfer material disposed between the substrate and the radiator plate.
